(19) United States
(12) Patent Application Publication
(10) Pub. No.: US 2009/0134498 A1
(43) Pub. Date: May 28, 2009

(54) SEMICONDUCTOR APPARATUS

(75) Inventors: Hiroaki IKEDA, Tokyo (JP); Masakazu Ishino, Tokyo (JP); Hideharu Miyake, Tokyo (JP); Shiro Uchiyama, Tokyo (JP); Yasuhiro Naka, Tokyo (JP); Nae Hisano, Tokyo (JP); Hisashi Tanie, Tokyo (JP); Kunihiko Nishi, Tokyo (JP); Hiroyuki Tenmei, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/273,590

(22) Filed: Nov. 19, 2008

(30) Foreign Application Priority Data
Nov. 20, 2007 (JP) 2007-300155

(51) Int. Cl. H01L 23/538; H01L 23/52; H01L 23/58

(52) U.S. Cl. 257/621; 257/E23.174

(57) ABSTRACT

The present invention includes a semiconductor element provided with an electrode passing through front and back sides. The electrode is formed as a cylinder including a hollow portion, and stress relaxing material is provided in the hollow portion, which is used to reduce stress that is induced between the semiconductor element and the electrode. The stress relaxing material is an elastic body made of resin material.

### BACKGROUND OF THE INVENTION

1. Field of the Invention

The present invention relates to a semiconductor apparatus, and particularly, to a semiconductor apparatus provided with a semiconductor element including an electrode (through electrode) which is provided to pass through the semiconductor element (chip).

2. Description of the Related Art

In recent years, a semiconductor apparatus is required to achieve further high-performance and downsizing.

In response to this request, such a configuration, wherein a through electrode is formed in a semiconductor element, and a plurality of the semiconductor elements are stacked to be connected to each other by using a bump connected to the through electrode, is focused on. Such a configuration is disclosed in the following documents, for example, Japanese Patent Laid-Open No. 10-223833; Japanese Patent Laid-Open No. 2004-152810; and Non-Patent Document (Japan Institute of Electronics Packaging Journal, Vol. 7, No. 1 (2004), pp. 40-46). In the above Japanese Patent Laid-Open No. 10-223833 and Japanese Patent Laid-Open No. 2004-152810, the configuration, wherein an electrode is formed by filling the inside of a through hole with metal material, is disclosed.

Taking into consideration electric characteristics, Cu, whose resistance is relatively small, is preferable as the metal material for filling the through electrode, which is also designated in Japanese Patent Laid-Open No. 2004-152810.

However, when Cu is used as material of the through electrode, it is concerned that thermal stress is induced because of the difference of the thermal expansion ratio between silicon configured in the semiconductor element and Cu (thermal expansion ratio of Cu: around 17 ppm/K, thermal expansion ratio of silicon: around 3 ppm/K). In particular, when the semiconductor element is connected to another electronic element or a board, the semiconductor element is normally heated up to nearly 300° C. In this case, large stress is induced around the electrode, a crack is induced in the silicon configured in the semiconductor element, as a result of which the semiconductor element may be broken. The large stress is induced around the electrode because the temperature is elevated when the semiconductor element is used, the electric characteristics are changed because of the induced stress, and the electric characteristics may become inappropriate.

### SUMMARY

The present invention seeks to solve one or more of the above problems, or at least to solve some of them.

In one embodiment, there is provided a semiconductor apparatus according to the present invention includes the semiconductor element provided with the electrode passing through the front and back sides,

the electrode is formed as a cylinder including a hollow portion, and stress relaxing material is provided in the hollow portion, which is used to reduce stress induced between the semiconductor element and the electrode. The following materials are, for example, used as the stress relaxing material: a low-elastic body which is made of photosensitive resin, and whose elasticity is relatively small, SiO2, polysilicon, conductive paste, and the like.

According to the present invention, it is possible to reduce stress induced around the electrode provided in the semiconductor element, and to prevent the semiconductor element from being broken as a result of a crack being induced in the semiconductor element, and to prevent inappropriate electric characteristics from being induced.

### BRIEF DESCRIPTION OF THE DRAWINGS

The above features and advantages of the present invention will be more apparent from the following description of certain preferred embodiments taken in conjunction with the accompanying drawings, in which:

FIGS. 1A, 1B, and 1C are views illustrating an area around an electrode of a semiconductor apparatus of the present exemplary embodiment;

FIG. 2 a diagram illustrating a finite element analysis model used for studying the semiconductor apparatus of the present exemplary embodiment;

FIGS. 3A and 3B are diagrams illustrating a result of analyzing stress distribution induced around the electrode when a hollow portion of the electrode of a semiconductor element is filled with photosensitive resin;

FIG. 4 is a diagram illustrating material properties of silicon, photosensitive resin, SiO2, and polysilicon which are used for the finite element method analysis in the present exemplary embodiment;

FIG. 5 is a diagram illustrating a stress-strain line of Cu, which is used for the finite element method analysis in the present exemplary embodiment;

FIG. 6 is a diagram illustrating a history of the analysis when the hollow portion of the electrode is filled with the photosensitive resin in the present exemplary embodiment;

FIG. 7 is a diagram illustrating a result of analyzing critical stress, in which a crack is induced in the semiconductor element, based on such an example in which crack is induced in flip-chip bonding;

FIGS. 8A and 8B are diagrams illustrating a history of the analysis when the hollow portion of the electrode of the semiconductor element is filled with SiO2, polysilicon, or conductive paste in the present exemplary embodiment;

FIGS. 9A and 9B are diagrams illustrating a result of analyzing stress distribution induced around the electrode when the hollow portion of the electrode of the semiconductor element is filled with SiO2 or polysilicon in the present exemplary embodiment;

FIG. 10 is a diagram illustrating a result of analyzing stress distribution induced around the electrode when the hollow portion of the electrode of the semiconductor element is filled with conductive paste in the present exemplary embodiment;

FIG. 11A is a cross-section view illustrating an area around the semiconductor element in the semiconductor apparatus of a first exemplary embodiment;

FIG. 11B is a cross-section view obtained by cutting, according to an A-B cutting line in FIG. 11A, the area around the electrode of the semiconductor element in the semiconductor apparatus of the first exemplary embodiment;

FIGS. 12A, 12B, 12C, and 12D are cross-section views describing a process for forming the electrode in the semiconductor element included in the semiconductor apparatus of the first exemplary embodiment;

FIGS. 13A, 13B, and 13C are cross-section views describing a process following FIG. 12D in the semiconductor apparatus of the first exemplary embodiment;

FIGS. 14A, 14B, 14C, and 14D are cross-section views describing a process following FIG. 13C in the semiconductor apparatus of the first exemplary embodiment;

FIG. 15 is a cross-section view illustrating the stack-type semiconductor apparatus whose structure is a package, in which the semiconductor element is mounted, in the semiconductor apparatus of the first exemplary embodiment;

FIG. 16 is a cross-section view illustrating another stack-type semiconductor apparatus whose structure is a package, in which the semiconductor element is mounted, in the semiconductor apparatus of the first exemplary embodiment;

FIG. 17 is a cross-section view illustrating an area around the electrode of the semiconductor element in the semiconductor apparatus of a second exemplary embodiment; and

FIG. 18 is a cross-section view illustrating an area around the electrode of the semiconductor element in the semiconductor apparatus of a third exemplary embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

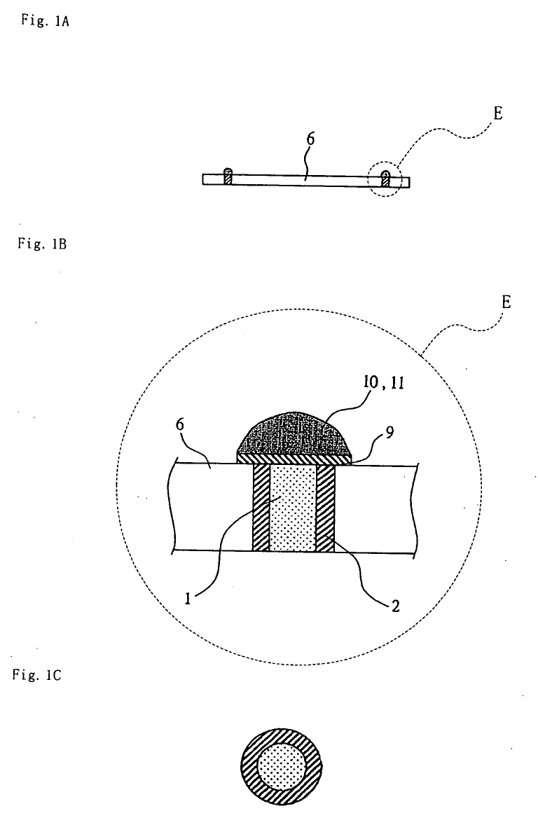

FIG. 1A to FIG. 1C illustrate an area around an electrode of a semiconductor apparatus of an exemplary embodiment. FIG. 1A is a cross-section view, and FIG. 1B is a cross-section view obtained by expanding part E of FIG. 1A. FIG. 1C is a plain view illustrating the electrode of FIG. 1B.

Referring now to FIG. 1A and FIG. 1B, a semiconductor apparatus according to a first embodiment of the present invention includes semiconductor element 6. This semiconductor element 6 is provided with cylindrical electrode 2 passing through front and back sides in a thickness direction. Stress relaxing material 1 is formed in a hollow portion of this electrode 2, which is used to reduce stress induced between semiconductor element 6 and electrode 2. Because of this stress relaxing material 1, stress is reduced in semiconductor element 6. In the present exemplary embodiment, as an exemplary configuration, such a case will be described in which semiconductor element 6 is formed of silicon, and electrode 2 is formed of Cu. As stress relaxing material 1, such a case will be described in which photosensitive resin is used, which is an example of low-elastic body made of resin material, and such a case will be described in which another material is used, such as SiO2, polysilicon, and conductive paste.

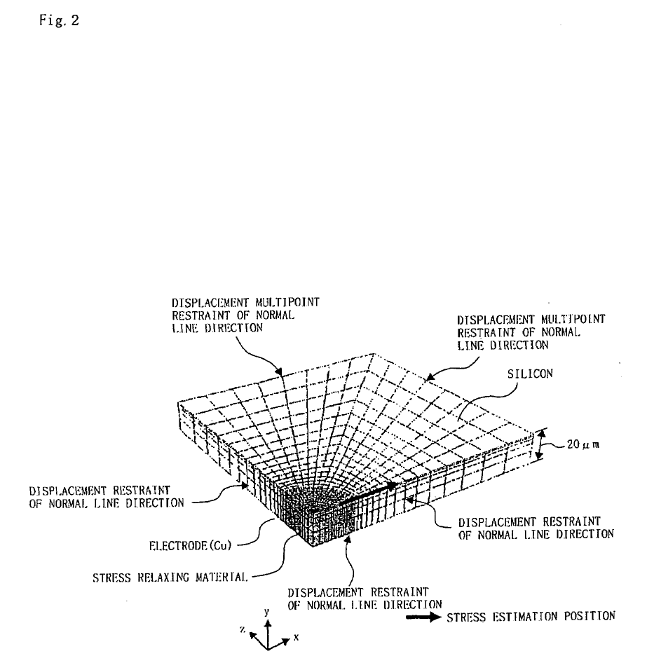

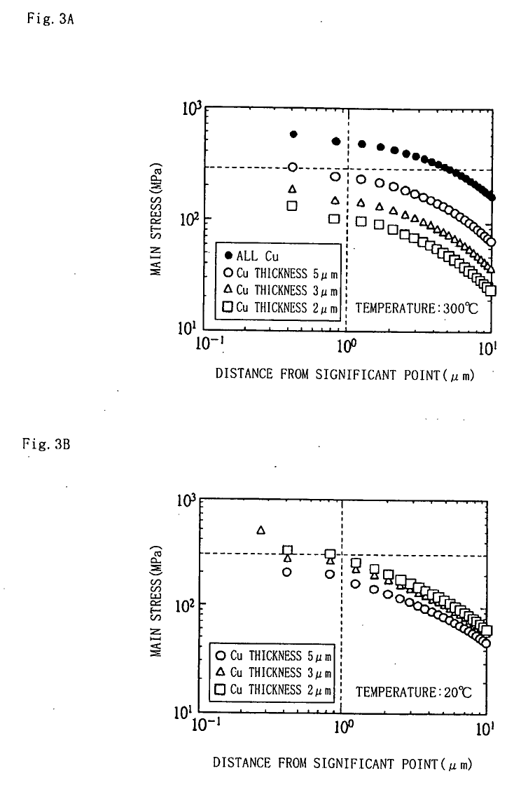

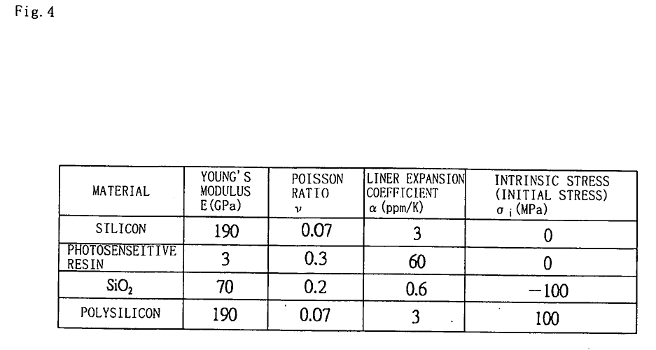

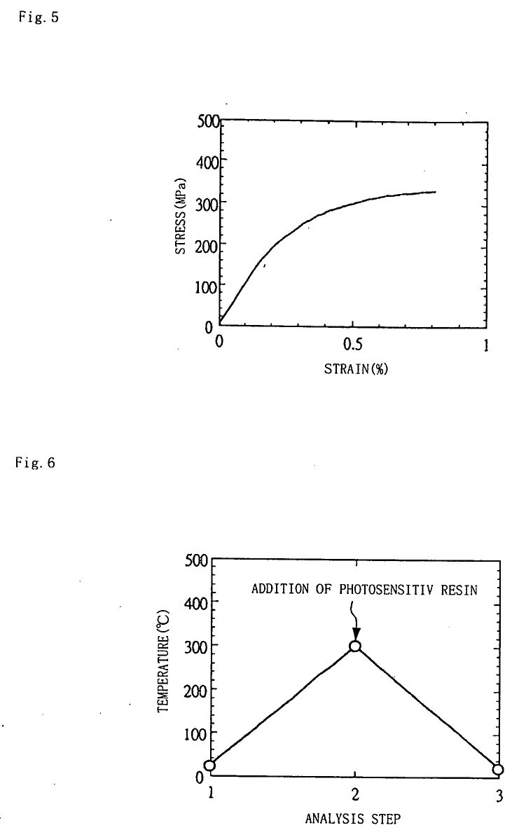

As illustrated in FIG. 1A to FIG. 10, in the semiconductor apparatus, connection pad 9 is provided in an edge part of electrode 2 of semiconductor element 6, and connection bumps 10 and 11 are formed in this connection pad 9. This semiconductor apparatus is analyzed by using a finite element method model illustrated in FIG. 2, and a result of the analysis is illustrated in FIG. 3A and FIG. 3B. Each value illustrated in FIG. 4 is used for material properties for silicon which is material configured in semiconductor element 6, and photosensitive resin which is material used for stress relaxing material 1. A stress-strain line illustrated in FIG. 5 is used for Cu which is material forming electrode 2. Meanwhile, it is assumed that a linear expansion coefficient of Cu is 17 ppm/K, and a Poisson ratio is 0.3. The photosensitive resin, which is material used for stress relaxing material 1, is baked at a temperature of around 300° C. to be hardened. Thus, as a history of the analysis illustrated in FIG. 6, the analysis is executed so that an element corresponding to the photosensitive resin is added at a temperature 300° C.

FIG. 3A and FIG. 3B illustrate stress distribution which is related to the distance from a stress concentration point (significant point) of the hollow portion of electrode 2 in an X axis direction (refer to FIG. 2). Stress distribution at the temperature of 300° C. is illustrated in FIG. 3A, and the stress distribution at the temperature of 20° C. is illustrated in FIG. 3B. At the temperature of 300° C., such a case is analyzed in which all the parts of the cylindrical electrode including the hollow portion of the cylindrical electrode are made of Cu, and such a case is also analyzed in which the inside of the hollow portion of the cylindrical electrode, which are made of Cu whose thickness is each 5 μm, 3 μm, and 2 μm, are filled with photosensitive resin. At the temperature of 20° C., such a case is analyzed that the inside of the hollow portion of the three cylindrical electrodes, which are made of Cu having three thickness respectively of 5 μm, 3 μm, and 2 μm, and the three cylindrical electrodes are filled with the photosensitive resin.

As is apparent from the result illustrated in FIG. 3A, when the inside of the hollow portion of cylindrical electrode 2 is filled with the photosensitive resin, stress at a temperature of 300° C. is decreased by half as compared with such a case in which all the parts of the cylindrical electrode including the hollow portion of the electrode are made of Cu. Because the thickness of cylindrical electrode 2 made of Cu is smaller, stress at a temperature of 300° C. is more decreased. On the other hand, as seen from the result illustrated in FIG. 3B, the relation between the stress and the thickness of the electrode at 20° C. is inverted from the relation between the stress and the thickness of the electrode at 300° C., and because the thickness of cylindrical electrode 2 made of Cu is smaller, the stress becomes larger.

This cause is estimated as follows. Stress at 300° C. corresponds to tensile stress induced because of the thermal expansion of Cu in a circle direction of cylindrical electrode 2. On the other hand, stress at 20° C. corresponds to tensile stress induced because of the shrinkage of the photosensitive resin in a direction which is vertical to the circle direction of electrode 2. Thus, because the thickness of cylindrical electrode 2 is larger, stress at 20° C. is more decreased.

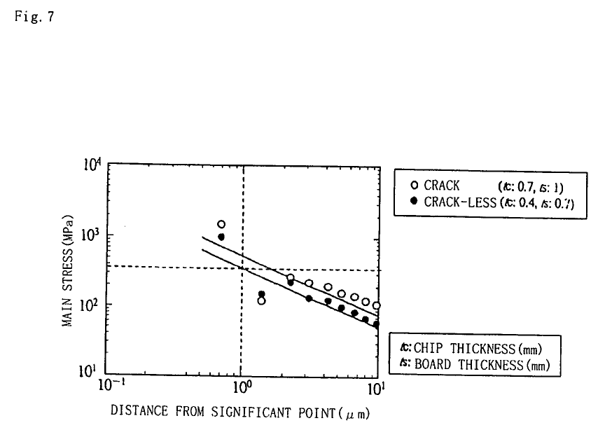

For comparison with the above example, such an example is analyzed in which a crack is induced in flip-chip bonding (Japan Institute of Electronics Packaging Journal, Vol. 7, No. 1 (2004), pp. 40-46). A result of the analysis is illustrated in FIG. 7. FIG. 7 illustrates stress distribution which is related to a distance from the significant point, at which the crack is induced, in a propagating direction of the crack. As illustrated in FIG. 7, when the stress is around 300 MPa or less when the distance from the significant point is 1 μm, the crack is not induced. In the stress distribution illustrated in FIG. 3, it can be determined from this fact that the above values of around 2 μm to 5 μm are appropriate for the thickness of Cu that forms cylindrical electrode 2.

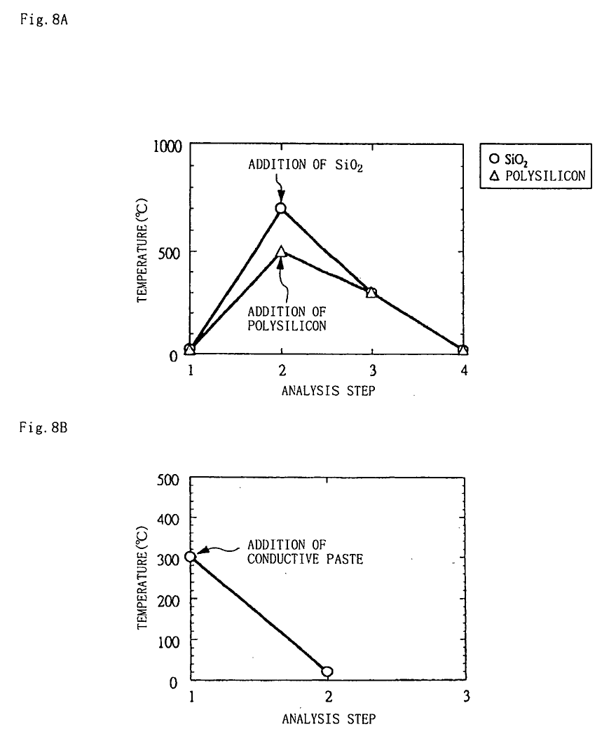

Next, a case is studied in which the inside of the hollow portion of cylindrical electrode 2 made of Cu is filled by using material other than photosensitive resin. As to other material, studies are made of each of the cases in which the inside of the hollow portion of cylindrical electrode is filled by using SiO₂, polysilicon and conductive paste. FIG. 8A and FIG. 8B illustrate a history of the analysis when each material is used. Since the film formation temperature for SiO₂ and for polysilicon is around 700° C. and 500° C. respectively, such film formation temperatures are designated to be the temperatures at which each element (material) is added (refer to FIG. 8A). Since the hardening temperature of the conductive paste is normally around 300° C., 300° C. is designated to be the temperatures at which the element is added (refer to FIG. 8B). The values illustrated in FIG. 4 are used as the material properties of SiO₂ and polysilicon. Cu-based material is used as the conductive paste, and the characteristic illustrated in FIG. 5 is used for the conductive paste. Meanwhile, it is assumed that the linear expansion coefficient is 17 ppm/K, and the Poisson ratio is 0.3 in this material.

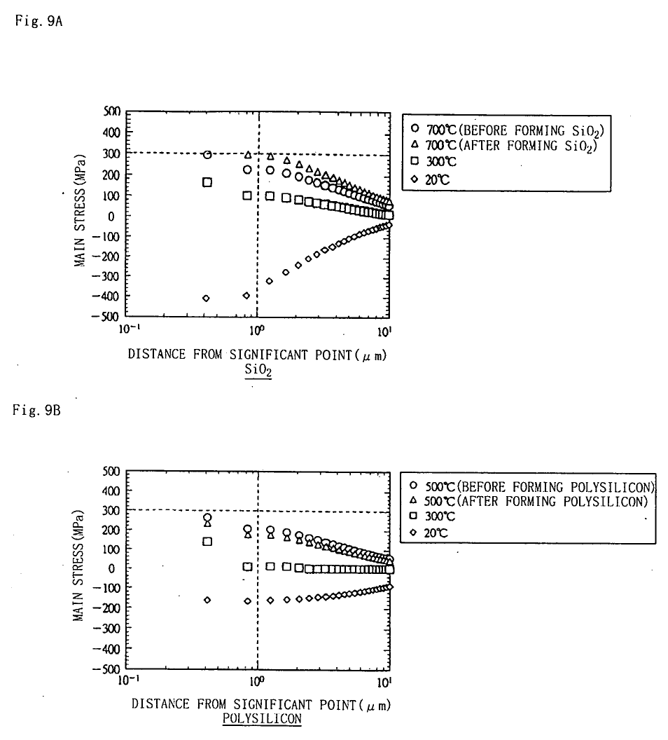

FIG. 9A and FIG. 9B illustrate results of the analysis when SiO2 and polysilicon are used. Meanwhile, each of the results corresponds to a case in which the thickness of the cylindrical electrode made of Cu is 3 μm. When SiO2 is used, the analysis is executed at each temperature of 700° C. (before and after SiO2 is formed), 300° C., and 200C. As seen from the results illustrated in FIG. 9A and FIG. 9B, stress is decreased in both cases in which SiO2 and polysilicon are used as compared with such a case illustrated in FIG. 3A in which all the parts including the hollow portion of the cylindrical electrode are made of Cu.

However, when SiO2 is used, because the forming temperature of SiO2 is higher than that of polysilicon, intrinsic stress is the compression stress, and the thermal expansion ratio of SiO2 is lower than that of polysilicon, the stress is slightly higher. When polysilicon is used, because the forming temperature of polysilicon is lower than that of SiO2, and intrinsic stress is the tensile stress, the amount of stress that is reduced is larger than that of SiO2, so that such a case in which polysilicon is used is advantageous. Meanwhile, each type of stress illustrated in FIG. 9A and FIG. 9B is stress in a circle direction of cylindrical electrode 2. When the thickness of the hollow portion of electrode 2 is larger than 3 μm, since the forming temperatures of both SiO2 and polysilicon are relatively high, stress at the forming temperature may exceed an acceptable value. Thus, it is preferable that the thickness of the hollow portion of electrode 2 that is made of Cu be equal to or less than 3 μm.

FIG. 10 illustrates a result of the analysis when the conductive paste is used. Here, such a case is analyzed in which the hollow portion of three electrode 2 which are made of Cu having thickness of respectively 5 μm, 3 μm, and 2 μm, and the inside of the hollow portion is filled with the conductive paste. FIG. 10 illustrates stress induced when the temperature is cooled to the room temperature after the conductive paste is hardened at 300° C. Stress at 300° C. is equal to the distribution illustrated in FIG. 3A. The stress of this analysis result is the stress that acts in a direction which is vertical to the circle direction of the cylindrical hollow portion of electrode 2. Since such a stress is stress induced since the conductive paste is heat-shrunk, as the thickness of a Cu film is larger, which forms electrode 2 before the conductive paste is applied, stress becomes lower, so that such a case is advantageous. However, as illustrated in FIG. 3A, since stress at 300° C. becomes higher as the thickness of the Cu film becomes larger, the thickness of around 5 μm, that is, around 5 μm, by rounding off, is appropriate for the thickness of the Cu film.

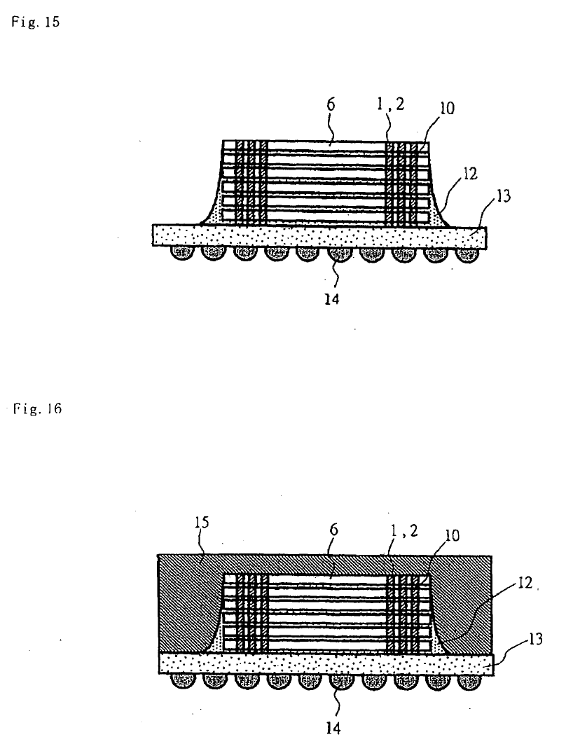

The semiconductor apparatus of the exemplary embodiment will be described below, in which the analysis result obtained by studying as above is adopted. In each exemplary embodiment, for example, as illustrated in FIG. 15 and FIG. 16 that are mentioned below, a package (module) structure is referred to as the semiconductor apparatus, in which a plurality of the semiconductor elements (chips) are stacked on a board to be electrically connected to each other.

### First Exemplary Embodiment

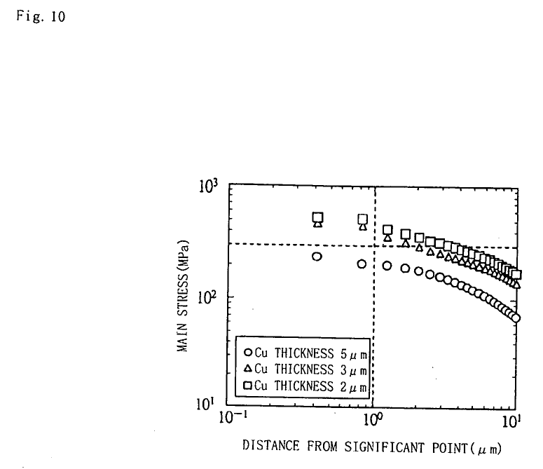

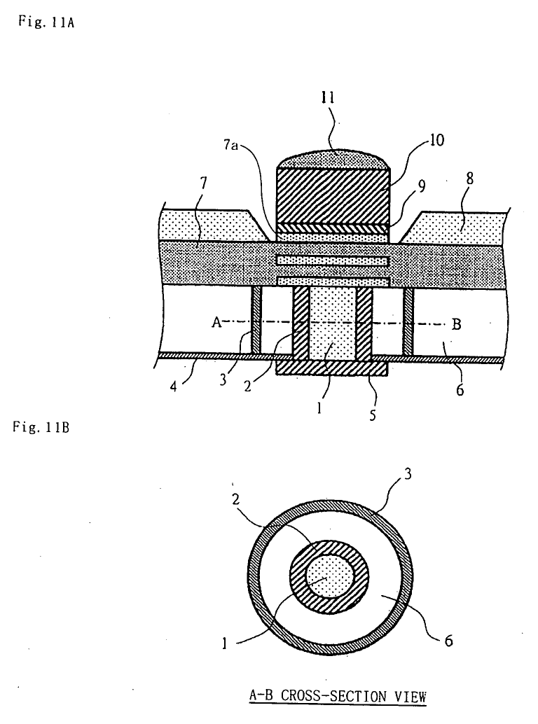

The semiconductor apparatus of a first exemplary embodiment will be described by referring to FIGS. 11A and 11B to FIG. 16.

FIG. 11A illustrates a cross-section view illustrating the electrode neighborhood of a chip of the semiconductor apparatus, and FIG. 11B illustrates a cross-section view obtained by cutting an A-B cutting line of FIG. 11A.

Referring now to FIG. 11A and FIG. 11B, the semiconductor apparatus of the present exemplary embodiment is provided with semiconductor element (chip) 6. This semiconductor element 6 is provided with cylindrical electrode 2 passing in a thickness direction through front and back sides of semiconductor element 6. Stress relaxing material 1 is provided in a hollow portion of this electrode 2. In semiconductor element 6, insulation layer 3 is formed as concentrically surrounding electrode 2 in an outer circle side of cylindrical electrode 2. The back side of semiconductor element 6 is, excluding electrode 2, covered with insulation film 4. Connection pad 5 is provided being electrically connected to an edge face of electrode 2, which is not covered with insulation film 4, in a back side of semiconductor element 6.

Circuit element 7 is formed on a surface of semiconductor element 6. Excluding a part, in which connection pad 9 for placing connection bumps 10 and 11 is formed, a surface of circuit element 7 is covered with insulation film 8. Connection pad 9 is formed being electrically connected to terminal 7a arranged in a part, which is not covered with insulation film 8, on the surface of circuit element 7. Connection bumps 10 and 11 are formed on a surface of connection pad 9.

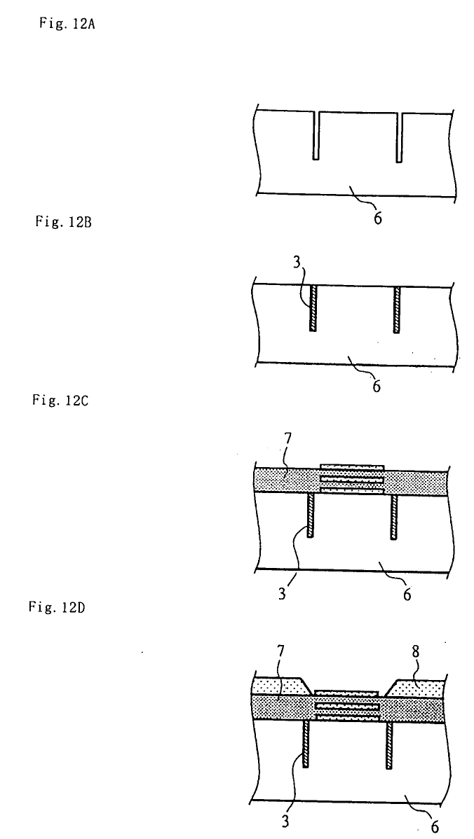

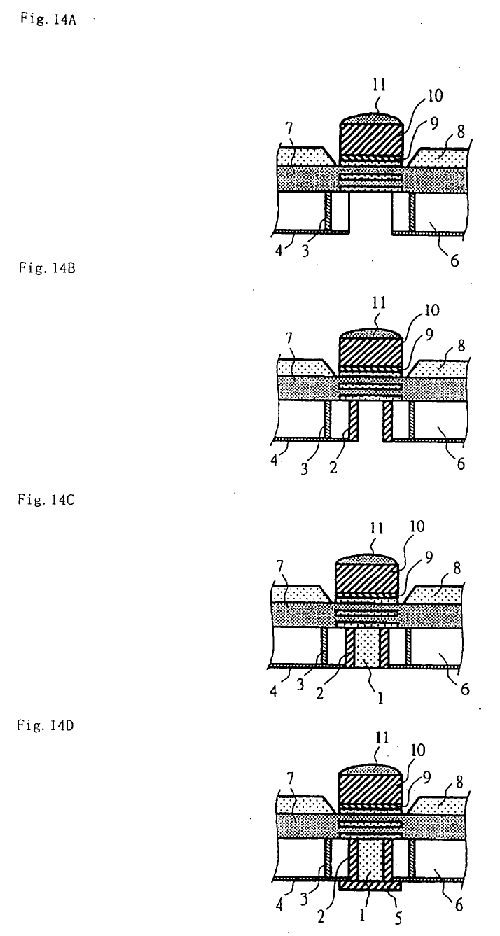

FIGS. 12 (12A, 12B, 12C, and 12D) to FIGS. 14 (14A, 14B, 14C, and 14D) illustrate cross-section views describing processes for forming electrode 2 in semiconductor element 6 included in the semiconductor apparatus of the present exemplary embodiment.

As illustrated in FIGS. 11A and 11B, at a first process, insulation layer 3 is made of SiO2 in the outer circle side of electrode 2. This insulation layer 3 is a barrier for preventing Cu which comprises electrode 2 from being diffused into silicon which comprises semiconductor element 6. As illustrated in FIG. 12A, a circular trench is first formed by dry etching on a surface of semiconductor element 6 that is made of silicon. Next, as illustrated in FIG. 12B, since a SiO2 film is formed in the trench, insulation layer 3 is formed. Meanwhile, when the SiO2 film is formed, it is desirable to further increase the insulation effect in which SiN is thinly formed as a ground in the trench. The circular trench for forming insulation layer 3 is formed so that the outer diameter is around 20 μm to 40 μm, the width is around 1 μm, and the depth is around 50 μm to 100 μm.

Next, as illustrated in FIG. 12C, circuit element 7 is formed on a surface of semiconductor element 6 that is made of silicon. Since a process for forming this circuit element 7 includes a process in which the temperature becomes equal to or more than 1000° C., it is necessary to implement a process for forming electrode 2 with Cu after the process for forming circuit element 7

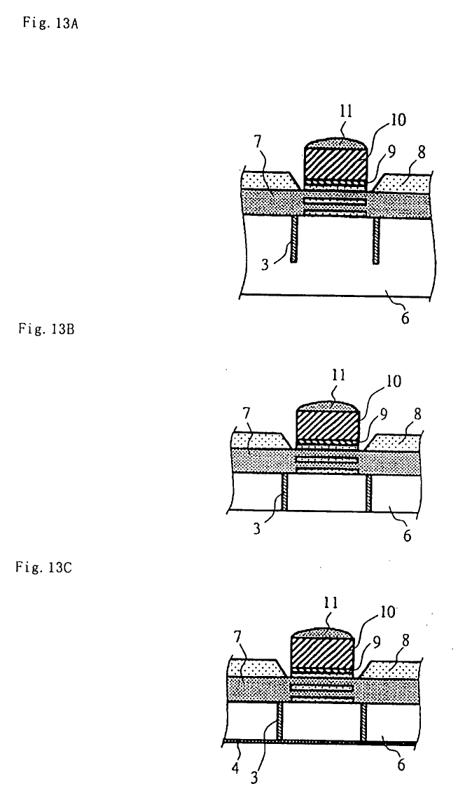

As illustrated in FIG. 12D, after the process for forming circuit element 7 has been completed, the surface of circuit element 7 is covered with insulation film 8 (for example, photosensitive resin) and insulation film 8 corresponding to a part, in which connection pad 9 for placing connection bumps 10 and 11 is formed, is eliminated by the etching, and an aperture is formed in insulation film 8. After that, as illustrated in FIG. 13A, connection pad 9 is formed in circuit element 7, and connection bumps 10 and 11 are formed on a surface of connection pad 9. In connection pad 9, a diffusion reducing film is formed as a ground with Ti, Cu, or the like, and Cu, Ni, or the like is formed on this ground. Connection bump 10 is made of Cu or solder (Sn-based metal). When connection bump 10 is made of the solder, since Cu is easily diffused into the solder, it is desirable that connection pad 9 be made of Ni. When the connection bump is made of metal material other than the solder, it is thought that connectivity is improved by thinly forming the solder in the head part of connection bump 10, that is, in connection bump 11.

As illustrated in FIG. 13B, after connection bumps 10 and 11 are formed, since a back side of semiconductor element 6 that is made of silicon, that is, an opposite side of a side, in which circuit element 7 is formed, is grounded, the thickness of the silicon is reduced. Since it is desirable that as many semiconductor elements as possible are stacked so that the total thickness becomes small, it is desirable that the thickness of the silicon per one semiconductor element is as thin as possible and that the thickness is caused to be at most around 50 μm.

Next, as illustrated in FIG. 13C, insulation film 4, whose thickness is around 1 μm, is made of SiN on a back side of ground semiconductor element 6. This insulation film 4 is used to prevent Cu which comprises connection pad 5 from being diffused into silicon which comprises semiconductor element 6. Insulation film 4 is not made of SiO2, but is made of SiN. This is because, when SiO2 is used, Cu is oxidized in a part that comes into contact with connection pad 5 that is made of Cu. It is relatively easy to control the intrinsic stress (film stress) for SiN. Since insulation film 4 is formed so that the intrinsic stress becomes the compression stress, it is possible to expect insulation film 4 to play a role as a coating film for preventing a crack from being induced in the silicon. This point is also advantageous.

As illustrated in FIG. 14A, after insulation film 4 is formed, a through hole is formed by the dry etching, whose diameter is around 10 μm to 30 μm, and this through hole passes in a thickness direction through the front and back sides of semiconductor element 6. Next, as illustrated in FIG. 14B, since a Cu film, whose thickness is 2 μm to 5 μm, is formed in an inner wall side of the through hole, electrode 2 is made of Cu. Meanwhile, in this case, since a thin film such as Ti and Cr is formed as the ground of the Cu film in the inner wall side of the through hole, the contact of the Cu film is improved, and since the ground also functions as the diffusion reducing film for Cu, this ground is advantageous. Here, the diameter of the through hole is formed smaller than the inner diameter of circular insulation layer 3. This is because the through hole can be more easily formed by enlarging the acceptable value of the through hole for position accuracy.

As illustrated in FIG. 14C, after electrode 2 is formed, the low-elastic body such as the photosensitive resin, that is, any one of elastic body, whose elasticity ratio is at largest 30 GPa or less, preferably 20 GPa or less, SiO2, polysilicon, or the conductive paste is formed as stress relaxing material 1 in the hollow portion which is made of the Cu film, thereby, stress is decreased. As illustrated in FIG. 14D, connection pad 5 is finally formed in the edge face of electrode 2 of the backside of semiconductor element 6, which is used to make a connection with the connection bump of another semiconductor element 6 which is stacked to this semiconductor element 6. Connection pad 5 is made of Cu, Ni, or the like.

Since a plurality of electrodes 2 as formed above are provided in the silicon which comprises semiconductor element 6, semiconductor element 6 including a plurality of electrodes 2 can be produced. The pitch of electrode 2 that is provided in such semiconductor element 6 is around 30 μm to 100 μm.

Meanwhile, while electrode 2 is formed in a cylindrical shape as illustrated in FIGS. 11A and 11B, and a cross-section shape is formed in a circular shape, the electrode may be formed in a polygonal shape such as a square shape, an octagonal shape in addition to a circular shape. When the pitch of the electrode is narrowed to the minimum, an area of the electrode can be secured such that the area has a square shape and the octagonal shape that is wider than circular shape, so that such shapes are advantageous. However, when the cross-section shape of the electrode is formed in the polygonal shape, since stress concentration is induced in a corner part of a polygonal shape, this point becomes disadvantageous as compared with a case in which the cross-section shape is formed in a circular shape.

As illustrated in FIG. 15 and FIG. 16, since a plurality of semiconductor elements 6 are stacked on the board to be electrically connected to each other by using above-formed electrode 2, the semiconductor apparatus, whose structure is a package (module) structure, can be produced.

The semiconductor apparatus illustrated in FIG. 15 is configured so that a plurality of semiconductor elements 6 are stacked on board 13 as being electrically connected at connection bump 10 through electrode 2 whose hollow portion is provided with stress relaxing material 1. This semiconductor apparatus is reinforced by filling resin, referred to as underfill 12, between each semiconductor element 6, and between semiconductor element 6 and board 13, and the semiconductor apparatus is structured so that the surface of semiconductor element 6 which is arranged in the top stage is exposed.

This semiconductor apparatus is a stack-type semiconductor apparatus in which package connection bump 14 is formed on a back side of board 13, and which is electrically connected to the outside through this package connection bump 14. Board 13 is, for example, made of resin, ceramic, silicon, or the like, and package connection bump 14 is made of solder, or the like.

The semiconductor apparatus illustrated in FIG. 16 is structured, as compared with the semiconductor apparatus illustrated in FIG. 15, so that the surface of semiconductor element 6, which is arranged in the top stage, is not exposed, and the stacked semiconductor elements 6 are sealed wholly by using sealing resin 15. Sealing resin 15 is, for example, made of epoxy-based resin, or the like.

When the structure illustrated in FIG. 15 is compared with the structure illustrated in FIG. 16, and when a large amount of heat is generated by the semiconductor element, and when a large amount of heat radiation is requested, the semiconductor apparatus illustrated in FIG. 15 is advantageous. On the other hand, when it is necessary to further improve the protection for semiconductor element 6, the semiconductor apparatus, in which the stacked semiconductor elements are sealed wholly, and which is illustrated in FIG. 16, is advantageous.

As described above, in the semiconductor apparatus of the present exemplary embodiment, electrode 2, which passes through the front and back sides of semiconductor element 6, includes the hollow portion, and stress relaxing material 1 is formed in this hollow portion, which is used to reduce thermal stress because of the difference of the thermal expansion ratio between semiconductor element 6 and electrode 2. Since stress induced around electrode 2 can be reduced by this configuration, it is possible to prevent semiconductor element 6 from being broken due to the induced crack. Since stress around electrode 2 is decreased, without the electric characteristics being changed in semiconductor element 6, it is possible to prevent the electric characteristics failure from being induced because of stress around electrode 2.

### Second Exemplary Embodiment

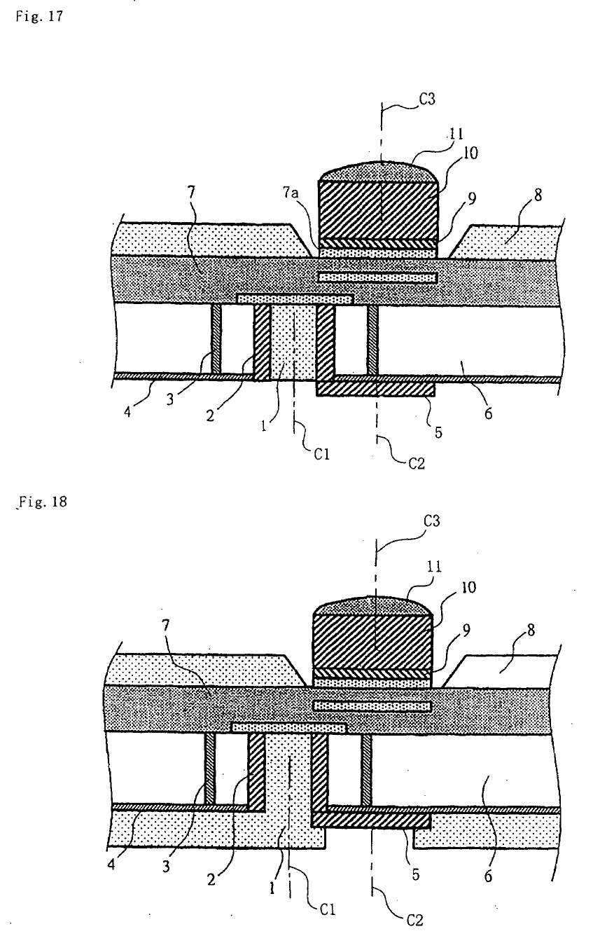

Referring to FIG. 17, the semiconductor apparatus of a second exemplary embodiment will now be described. FIG. 17 illustrates a cross-section view illustrating the electrode neighborhood of the semiconductor element included in the semiconductor apparatus of the present exemplary embodiment.

As illustrated in FIG. 17, a point of difference between the semiconductor element included in the semiconductor apparatus of the present exemplary embodiment and the semiconductor element included in the semiconductor apparatus of the first exemplary embodiment is that central axis C2 of connection pad 5, which is electrically connected to a connection bump of another semiconductor element stacked to the semiconductor element, is arranged at a position separated from central axis C1 of cylindrical electrode 2.

In this configuration, particularly, when the inside of the hollow portion of electrode 2 is filled with photosensitive resin used as stress relaxing material, a structure in which the photosensitive resin is closed in the hollow portion, as in the structure of the first exemplary embodiment, by closing an aperture of the hollow portion of electrode 2 with connection pad 5, needs to have the photosensitive resin that is to be used adequately managed so as to prevent a burst, because of moisture at the high temperature, from being induced when the moisture is absorbed by the photosensitive resin. In the structure of the first exemplary embodiment, the photosensitive resin is provided only inside the hollow portion of electrode 2, and also the photosensitive resin is formed so as to be on the same flat surface as the edge face of cylindrical electrode 2, so that a complex technique is necessary. Even when the inside of the hollow portion of electrode 2 is filled by using SiO2, this structure requires execution of some process such as SiN being formed on SiO2, to prevent oxidization because of the diffusion of the oxygen of SiO2, which is induced when connection pad 5 made of Cu, or the like, is directly formed on SiO2 provided in the hollow portion. As seen from such a viewpoint, in the structure of the present exemplary embodiment, a complex technique, that is used to provide photosensitive resin in the hollow portion of electrode 2, becomes unnecessary, as a result of which is possible to reduce production costs and to improve productivity.

That is, for the semiconductor element included in the semiconductor apparatus of the present exemplary embodiment, on the back side of semiconductor element 6, connection pad 5 is configured to be electrically connected to a part of the edge face of cylindrical electrode 2 which passes in the thickness direction through the front and back sides of semiconductor element 6. In particular, regarding a relative position between connection pad 5 and electrode 2, the position of central axis C2 of connection pad 5 and the position of central axis C1 of the hollow portion of electrode 2 are shifted in a direction, which is orthogonal to central axes C1 and C2, by at least a diameter length of the hollow portion of cylindrical electrode 2, and the edge face of the hollow portion of electrode 2 is opened. In addition, stress relaxing material 1 is provided in the hollow portion of electrode 2.

Circuit element 7 is formed on a surface side of semiconductor element 6, and the surface of circuit element 7 is, excluding a part, covered with insulation film 8. Terminal 7a of circuit element 7 is arranged in a part, which is not covered with insulation film 8, of the surface of circuit element 7, and connection pad 9 is formed to be electrically connected to this terminal 7a. Connection bumps 10 and 11 are formed on a surface of this connection pad 9. Central axis C3 of connection bumps 10 and 11 formed on the surface side of this semiconductor element 6 is caused to nearly correspond to central axis C2 of connection pad 5 formed on the back side of semiconductor element 6 taking into consideration that a plurality of semiconductor elements 6 are stacked.

In the process for forming electrode 2 in semiconductor element 6 of the semiconductor apparatus of the present exemplary embodiment, before the inside of the hollow portion of electrode 2 is filled with stress relaxing material 1 (photosensitive resin, SiO2, polysilicon, and conductive paste), connection pad 5 is formed, and after connection pad 5 is formed, stress relaxing material 1 is formed in the hollow portion. The present exemplary embodiment is, excluding the above point, the same as the first exemplary embodiment. Since many above-formed electrodes 2 are provided in the silicon which comprises semiconductor element 6, it is possible to produce semiconductor element 6 including a lot of electrodes 2.

In the present exemplary embodiment, as compared with the first exemplary embodiment, space, which is necessary to form electrodes 2, is large. Thus, in the present exemplary embodiment, the smallest pitch of the formable connection bump becomes larger than that of the first exemplary embodiment. However, in the present exemplary embodiment, it is possible to further reduce the production cost, and to further improve productivity as compared with the first exemplary embodiment, and as in the first exemplary embodiment, since stress relaxing material 1 is formed in the hollow portion of electrode 2 which passes through the front and back sides of semiconductor element 6, it is possible to reduce stress induced around electrode 2. Thus, since semiconductor element 6 is prevented from being broken because a crack is induced in semiconductor element 6, and because stress is reduced, the electric characteristics of semiconductor element 6 are not changed, so that it is possible to prevent the failure of the electric characteristics due to stress induced around electrode 2.

### Third Exemplary Embodiment

Referring to FIG. 18, the semiconductor apparatus of the present exemplary embodiment will be described. FIG. 18 illustrates a cross-section view around the electrode of the semiconductor element included in the semiconductor apparatus of the present exemplary embodiment.

The semiconductor element included in the semiconductor apparatus of the present exemplary embodiment is configured so that the inside of the hollow portion of electrode 2 is filled with photosensitive resin used as stress relaxing material 1, and the structure of the back side of semiconductor element 6 is different from that of the second exemplary embodiment.

That is, for the semiconductor element included in the semiconductor apparatus of the present exemplary embodiment, on the back side of semiconductor element 6, connection pad 5 is formed to be electrically connected to a part of the edge face of electrode 2 on the surface of electrode 2 which passes through the front and back sides of semiconductor element 6, and connection pad 5 is exposed, the inside of the hollow portion of electrode 2 is filled with the photosensitive resin, and the photosensitive resin is formed so as to cover insulation film 4.

In the process for forming electrode 2 in semiconductor element 6 of the semiconductor apparatus of the present exemplary embodiment, when the inside of the hollow portion of electrode 2 is filled with photosensitive resin, in addition to the inside of the hollow portion of electrode 2 being filled, the entire back side of semiconductor element 6 is covered with the photosensitive resin. After that, the photosensitive resin corresponding to connection pad 5 is eliminated by etching, and only connection pad 5 is exposed. The present exemplary embodiment is, excluding this point, the same as the first exemplary embodiment. Since many above-formed electrodes 2 are provided in the silicon which comprise semiconductor element 6, the semiconductor element including many electrodes 2 can be produced.

Even in the semiconductor apparatus of the present exemplary embodiment, as in the second exemplary embodiment, the smallest pitch of the formable connection bump becomes larger than that of the first exemplary embodiment. However, even in the present exemplary embodiment, it is possible to further reduce production cost, and to further improve productivity as compared with the first exemplary embodiment, and as in the first exemplary embodiment, since stress relaxing material 1 is formed in the hollow portion of this electrode 2 which passes through the front and back sides of semiconductor element 6, it is possible to decrease stress induced around electrode 2. Thus, since semiconductor element 6 is prevented from being broken because a crack is induced in semiconductor element 6, and because the stress is reduced, the electric characteristics of semiconductor element 6 are not changed, so that it is possible to prevent failure of the electric characteristics from being induced due to stress induced around electrode 2.

Accordingly, while the present invention has been described herein in detail in relation to its preferred embodiment, it is to be understood that this disclosure is only illustrative and exemplary of the present invention and is made merely for purposes of providing a full and enabling disclosure of the invention. The foregoing disclosure is not intended or to be constructed to limit the present invention or otherwise to exclude any such other embodiments, adaptations, variations, modifications and equivalent arrangements, the present invention being limited only by the claims and the equivalents thereof.

The present invention can be utilized in the semiconductor apparatus in which the semiconductor element including the electrode, which is provided to pass through the front and back sides of the semiconductor element, is mounted, and specifically, the present invention can be preferably utilized in the stack-type semiconductor apparatus in which a plurality of the semiconductor elements are stacked and electrically connected to each other.

It is understood that the present invention is not limited to the above embodiments, but may be modified and changed without departing from the scope and spirit of the invention.

What is claimed is:

1. A semiconductor apparatus, comprising:
a semiconductor element provided with an electrode passing through front and back sides of the semiconductor element,
wherein the electrode is formed as a cylinder including a hollow portion, and stress relaxing material is provided in the hollow portion, the stress relaxing material being used to reduce stress induced between the semiconductor element and the electrode, and
the stress relaxing material is an elastic body made of resin material.

2. The semiconductor apparatus according to claim 1,
wherein an insulation layer is formed in an outer circle side of the electrode so as to surround the electrode.

3. The semiconductor apparatus according to claim 1,
wherein one side of the front and back sides of the semiconductor element is, except for an edge face of the electrode, covered with an insulation film.

4. The semiconductor apparatus according to claim 3,
wherein the insulation film is made of SiN.

5. The semiconductor apparatus according to claim 1, further comprising:
a cylindrical connection pad which is electrically connected to the edge face of the cylindrical electrode, and is formed on one side of the front and back sides of the semiconductor element,
wherein the connection pad and the electrode are formed at such a position that a central axis of the connection pad and a central axis of the electrode are shifted by at least a diameter length of the hollow portion of the electrode.

6. The semiconductor apparatus according to claim 1,
wherein an elasticity ratio of the elastic body is 30 GPa or less.

7. The semiconductor apparatus according to claim 1,
wherein the elastic body is made of photosensitive resin.

8. A semiconductor apparatus, comprising:
a semiconductor element provided with an electrode passing through front and back sides of the semiconductor element,
wherein the electrode is formed as a cylinder including a hollow portion, and stress relaxing material is provided in the hollow portion, the stress relaxing material being used to reduce stress induced between the semiconductor element and the electrode, and
the stress relaxing material is made of SiO2.

9. A semiconductor apparatus, comprising:
a semiconductor element provided with an electrode passing through front and back sides of the semiconductor element,
wherein the electrode is formed as a cylinder including a hollow portion, and stress relaxing material is provided in the hollow portion, the stress relaxing material being used to reduce stress induced between the semiconductor element and the electrode, and
the stress relaxing material is made of polysilicon.

10. A semiconductor apparatus, comprising:
a semiconductor element provided with an electrode passing through front and back sides of the semiconductor element,
wherein the electrode is formed as a cylinder including a hollow portion, and stress relaxing material is provided in the hollow portion, the stress relaxing material being used to reduce stress induced between the semiconductor element and the electrode, and
the stress relaxing material is made of conductive paste.

11. The semiconductor apparatus according to claim 7,
wherein thickness of the hollow portion of the electrode is in a range from 2 μm to 5 μm.

12. The semiconductor apparatus according to claim 8,
wherein the thickness of the hollow portion of the electrode is equal to or less than 3 μm.

13. The semiconductor apparatus according to claim 9,
wherein the thickness of the hollow portion of the electrode is equal to or less than 3 μm.

14. The semiconductor apparatus according to claim 10,
wherein the thickness of the hollow portion of the electrode is equal to or less than 3 μm.

15. The semiconductor apparatus according to claim 10,
wherein the thickness of the hollow portion of the electrode is 5 μm.

16. The semiconductor apparatus according to claim 1,
wherein a plurality of the semiconductor elements are stacked on a board to be electrically connected to each other.

17. The semiconductor apparatus according to claim 16,
wherein a plurality of the semiconductor elements stacked on the board are sealed by using resin material.
